(19) United States
(12) Patent Application Publication
(10) Pub. No.: US 2020/0225691 A1
(43) Pub. Date: Jul. 16, 2020

(54) MOVABLE HANDLE

(71) Applicant: FIVETECH TECHNOLOGY INC., New Taipei City (TW)

(72) Inventor: Ting-Jui Wang, New Taipei City (TW)

(21) Appl. No.: 16/838,173

(22) Filed: Apr. 2, 2020

Related U.S. Application Data
(63) Continuation-in-part of application No. 15/430,948, filed on Feb. 13, 2017, now Pat. No. 10,656,667.

(30) Foreign Application Priority Data
Feb. 19, 2016 (TW) 105202437

(51) Int. Cl. G05G 1/04; G05G 5/05; G05G 5/04; G05G 7/00; H05K 5/02

(52) U.S. Cl. CPC G05G 1/04; G05G 5/05; H05K 5/023; G05G 7/00; G05G 5/04

(57) ABSTRACT

A movable handle includes a movable member and a seat, both of which can be made of a plastic, a metal or a composite material. The movable member includes a main body and a bent portion. The main body can be bar-shaped, block-like, ball-shaped, wedge-shaped or in any other suitable shape, and the bent portion can be bent inward, outward or in any other direction relative to the main body. The main body of the movable member is movably assembled to the seat, and the seat is connected to a first object, such that the movable member is indirectly connected to the first object via the seat and can be turned or moved upward and downward or leftward and rightward on and relative to the first object.

### CROSS-REFERENCE TO RELATED APPLICATION

This application is a continuation-in-part patent application of U.S. application Ser. No. 15/430,948 filed on Feb. 13, 2017, the entire contents of which are hereby incorporated by reference for which priority is claimed under 35 U.S.C. § 120.

### BACKGROUND OF THE INVENTION

### 1. Field of the Invention

The present invention relates to a handle, and more particularly, to a movable handle having a seat, which is connected to a first object, and a movable member assembled to the seat and can be turned or moved upward, downward, leftward or rightward relative to the seat.

### 2. Description of the Related Art

Conventionally, the mounting structure on a handle for connecting the handle to a chassis of an electric product or some other object usually includes a threaded hole provided near an end of the handle and a through hole provided on the chassis or the object. A screw is extended from a rear side of the through hole to be locked to the threaded hole on the handle, such that the handle is fixed to the chassis or the object. With the above mounting structure, the handle connected to the chassis or the object is not permitted to move, such as to rotate or to move upward and downward or leftward and rightward, relative to the chassis or the object. To provide a movable handle, other special assembling structure must be additionally designed. In the case of a conventional movable handle assembling structure that involves a relatively complicated structure, it requires increased manufacturing cost and is therefore less competitive in the market. On the other hand, in the case of a conventional movable handle assembling structure that involves only simple screws or nuts, the screw heads or the nuts will have one side in contact with one surface of the handle. When the handle is operated and turned, it tends to bring the screws or the nuts to rotate along with it to finally cause loosened screws or nuts. Therefore, it is an object of the present invention to develop a movable handle that has simple structure and does not require high manufacturing cost, and can be turned or be moved upward and downward or leftward and rightward without the problem of causing loosened screws or nuts.

### BRIEF SUMMARY OF THE INVENTION

In view of the drawbacks of the conventional handles mounted on chassis or other objects, it is a primary object of the present invention to develop a movable handle that can be turned or be moved upward and downward or leftward and rightward and can be used to actuate another functional member.

In order to achieve the above and other objects, the present invention provides a movable handle, which preferably includes a movable member including a main body; and a seat, movably assembled to the main body of the movable member, such that the movable member is capable of moving. The movable member includes an operation portion and a pushing portion. The operation portion is movably mounted on the seat. The pushing portion is movably mounted on the operation portion. The operation portion controls the pushing portion to extend out of the seat to form a pushed-out state, or the operation portion controls the pushing portion to move to the seat to form a retracted state; wherein one end of the operation portion includes a pusher portion, and one end of the pushing portion includes an abutting portion. The pusher portion abuts against the abutting portion, the pusher portion is an inclined body, and the abutting portion is a rolling body.

The present invention further provides a movable handle, which preferably includes a movable member including a main body; and a seat, movably assembled to the main body of the movable member, such that the movable member is capable of moving. The movable member includes an operation portion and a pushing portion. The operation portion is movably mounted on the seat. The pushing portion is movably mounted on the operation portion. The operation portion controls the pushing portion to extend out of the seat to form a pushed-out state, or the operation portion controls the pushing portion to move to the seat to form a retracted state; wherein one end of the operation portion includes a pusher portion, and one end of the pushing portion includes an abutting portion. The pusher portion abuts against the abutting portion, the abutting portion is an inclined body, and the pusher portion is a rolling body.

The present invention further provides a movable handle, which preferably includes a movable member including a main body; and a seat, movably assembled to the main body of the movable member, such that the movable member is capable of moving. The movable member includes an operation portion and a pushing portion. The operation portion is movably mounted on the seat. The pushing portion is movably mounted on the operation portion. The operation portion controls the pushing portion to extend out of the seat to form a pushed-out state, or the operation portion controls the pushing portion to move to the seat to form a retracted state; wherein one end of the operation portion includes a pusher portion, and one end of the pushing portion includes an abutting portion. The pusher portion abuts against the abutting portion, the abutting portion is an inclined body, and the pusher portion is a rolling body. Or the pusher portion is an inclined body, and the abutting portion is a rolling body. The pushing portion includes a rod body. The abutting portion is mounted at one end of the rod body. The rod body is sleeved with an elastic element and includes one or two blocking portions. The blocking portions abut against one end of the elastic element or abut against the two ends of the elastic element respectively. The blocking portion includes a limiting portion, and the seat includes a corresponding limiting portion connecting to the limiting portion. The blocking portion includes an anti-rotation portion, and the pushing portion includes a corresponding anti-rotation portion for anti-rotating correspondingly. When two blocking portions are provided, one of the blocking portions includes a limiting portion, and the seat includes a corresponding limiting portion connecting to the limiting portion. The blocking portion includes an anti-rotation portion, and the pushing portion includes a corresponding anti-rotation portion for anti-rotating correspondingly, preventing the rolling body of the pushing portion from rotating during movement.

The present invention further provides a movable handle, which preferably includes a movable member including a main body; and a seat, movably assembled to the main body of the movable member, such that the movable member is capable of moving. The movable member includes an operation portion and a pushing portion. The operation portion is movably mounted on the seat. The pushing portion is movably mounted on the operation portion. The operation portion controls the pushing portion to extend out of the seat to form a pushed-out state, or the operation portion controls the pushing portion to move to the seat to form a retracted state; wherein one end of the operation portion includes a pusher portion, and one end of the pushing portion includes an abutting portion. The pusher portion abuts against the abutting portion, the abutting portion is an inclined body, and the pusher portion is a rolling body. Or the pusher portion is an inclined body, and the abutting portion is a rolling body. The movable handle includes two elastic elements. One end of one of elastic elements abuts against the main body, and the other end abuts against the seat; and one end of the other elastic element abuts against the pushing portion, the other end abuts against the seat.

The present invention further provides a movable handle, which preferably includes a movable member including a main body; and a seat, movably assembled to the main body of the movable member, such that the movable member is capable of moving. The movable member includes an operation portion and a pushing portion. The operation portion is movably mounted on the seat. The pushing portion is movably mounted on the operation portion. The operation portion controls the pushing portion to extend out of the seat to form a pushed-out state, or the operation portion controls the pushing portion to move to the seat to form a retracted state; wherein one end of the operation portion includes a pusher portion, and one end of the pushing portion includes an abutting portion. The pusher portion abuts against the abutting portion, the abutting portion is an inclined body, and the pusher portion is a rolling body. Or the pusher portion is an inclined body, and the abutting portion is a rolling body. The pushing portion includes a rod body. The abutting portion is mounted at one end of the rod body. The rod body is sleeved with an elastic element and includes one or two blocking portions. The blocking portions abut against one end of the elastic element or abut against the two ends of the elastic element respectively. The blocking portion includes a limiting portion, and the seat includes a corresponding limiting portion connecting to the limiting portion. The blocking portion includes an anti-rotation portion, and the pushing portion includes a corresponding anti-rotation portion for anti-rotating correspondingly. When two blocking portions are provided, one of the blocking portions includes a limiting portion, and the seat includes a corresponding limiting portion connecting to the limiting portion. The blocking portion includes an anti-rotation portion, and the pushing portion includes a corresponding anti-rotation portion for anti-rotating correspondingly, preventing the rolling body of the pushing portion from rotating during movement. The movable handle includes two elastic elements. One end of one of elastic elements abuts against the main body, and the other end abuts against the seat; and one end of the other elastic element abuts against the pushing portion, the other end abuts against the seat.

The present invention further provides a movable handle, which preferably includes a movable member including a main body; and a seat, movably assembled to the main body of the movable member, such that the movable member is capable of moving. The movable member includes an operation portion and a pushing portion. The operation portion is movably mounted on the seat. The pushing portion is movably mounted on the operation portion. The operation portion controls the pushing portion to extend out of the seat to form a pushed-out state, or the operation portion controls the pushing portion to move to the seat to form a retracted state; wherein one end of the operation portion includes a pusher portion, and one end of the pushing portion includes an abutting portion. The pusher portion abuts against the abutting portion and the pushing portion includes a rod body. The rod body includes a blocking portion, and the blocking portion includes a sliding portion for correspondingly sliding to abut against the seat.

In the movable handle described above, the pushing portion includes a rod body, and the abutting portion is mounted at one end of the rod body. The rod body is sleeved with an elastic element and includes one or two blocking portions. The blocking portions abut against one end of the elastic element or abuts against the two ends of the elastic element respectively.

The movable handle described above further includes a rod body. The rod body includes a blocking portion having a limiting portion, and the seat includes a corresponding limiting portion connecting to the limiting portion.

In the movable handle described above, the blocking portion includes an anti-rotation portion, and the pushing portion includes a corresponding anti-rotation portion for anti-rotating correspondingly.

The movable handle described above further includes a blocking portion, the blocking portion includes a limiting portion, and the seat includes a corresponding limiting portion connecting to the limiting portion. The blocking portion includes an anti-rotation portion, and the pushing portion includes a corresponding anti-rotation portion for anti-rotating correspondingly, preventing the rolling body of the pushing portion from rotating during movement.

The movable handle described above further includes two elastic elements, one end of one of elastic elements abuts against the main body, and the other end abuts against the seat; and one end of the other elastic element abuts against the pushing portion, the other end abuts against the seat.

In the movable handle described above, the rolling body is a unidirectional wheel, a universal ball, or a rolling module formed by a large universal ball and several small universal balls.

The present invention further provides a movable handle, which preferably includes a movable member including a main body; and a seat, movably assembled to the main body of the movable member, such that the movable member is capable of moving. The movable member includes an operation portion, a pushing portion and a driving portion. The operation portion is movably mounted on the seat. The pushing portion is movably mounted on the operation portion. The driving portion is connected to the main body and the operation portion. The driving portion may drive the operation portion, such that the operation portion may control the pushing portion to extend out of the seat to form a pushed-out state, or the operation portion may control the pushing portion to move to the seat to form a retracted state.

In the movable handle described above, one end of the operation portion includes a pusher portion. The pushing portion includes a rod body. One end of the rod body includes a blocking portion. The pusher portion abuts against the abutting portion. The pusher portion is an inclined body, and the abutting portion is a rolling body.

In the movable handle described above, the rod body is sleeved with a first elastic element and includes a blocking portion. One end of the first elastic element abuts against the seat, and the other end of the first elastic element abuts against the blocking portion.

In the movable handle described above, one end of the operation portion includes a pusher portion, and one end of the pushing portion includes an abutting portion. The pusher portion abuts against the abutting portion. The pusher portion is a rolling body, and the abutting portion is an inclined body.

In the movable handle described above, the driving portion includes a rotating shaft and a driving member. The rotating shaft is movably mounted on the seat and connected to the main body, and the driving member is mounted on the rotating shaft and connected to the operation portion.

The movable handle described above further includes a second elastic element. One end of the second elastic element is connected to the seat, and the other end of the second elastic element is connected to the rotating shaft.

The present invention further provides a movable handle, which preferably includes a movable handle. The movable handle includes a movable member including a main body; and a seat, movably assembled to the main body of the movable member, such that the movable member is capable of moving. The movable member includes an operation portion and a pushing portion. The operation portion is movably mounted on the seat. The pushing portion is movably mounted on the operation portion. The operation portion may control the pushing portion to extend out of the seat to form a pushed-out state, or the operation portion may control the pushing portion to move to the seat to form a retracted state.

In the movable handle described above, a first elastic element is mounted between the movable member and the seat. One end of the first elastic element abuts against the movable member, and the other end of the first elastic element abuts against the seat.

In the movable handle described above, the operation portion includes a tie rod, a connecting rod, and a shaft body. The tie rod is movably connected to the movable member, the shaft body is movably mounted on the seat and connected to the tie rod and the connecting rod. The connecting rod is movably connected to the pushing portion.

In the movable handle described above, the pushing portion includes a rod body, and one end of the rod body includes a blocking portion.

The rod body is sleeved with a second elastic element. One end of the second elastic element abuts against the seat, and the other end of the second elastic element abuts against the blocking portion.

The present invention further provides a movable handle, which preferably includes a movable member including a main body; and a seat, movably assembled to the main body of the movable member, such that the movable member is capable of moving. The movable member includes an operation portion and a pushing portion. The operation portion is movably mounted on the seat. The pushing portion is movably mounted on the operation portion. The operation portion may control the pushing portion to extend out of the seat to form a pushed-out state, or the operation portion may control the pushing portion to move to the seat to form a retracted state.

The present invention further provides a movable handle, which preferably includes a movable member including a main body; and a seat, movably assembled to the main body of the movable member, such that the movable member is capable of moving. The movable member includes an operation portion and a pushing portion. The operation portion is movably mounted on the seat. The pushing portion is movably mounted on the operation portion.

The present invention further provides a movable handle, which preferably includes a movable member including a main body; and a seat, movably assembled to the main body of the movable member, such that the movable member is capable of moving.

In summary, the movable handle according to the present invention has a seat connected to an object, and a movable member movably assembled to the seat and can therefore be turned, or moved upward and downward, or moved leftward and rightward relative to the seat and the object.

### BRIEF DESCRIPTION OF THE DRAWINGS

FIG. 1 is an exploded perspective view of a movable handle according to a first preferred embodiment of the present invention.

FIG. 2 is an assembled, partially sectioned side view of the movable handle according to the first preferred embodiment as shown in FIG. 1.

FIG. 3 is a front view of the movable handle according to the first preferred embodiment as shown in FIG. 1.

FIG. 4 is a front view showing a movable member of the movable handle of FIG. 1 is turned.

FIG. 5 is an assembled, partially sectioned top view showing the movable member of the movable handle of FIG. 1 is moved to actuate an actuator member.

FIG. 6 is an assembled, partially sectioned side view showing a variant of the movable handle according to the first preferred embodiment, in which a seat of the movable handle includes a second coupling section.

FIG. 7 is an assembled, partially sectioned side view showing the movable handle according to the first preferred embodiment includes an elastic element in the form of a torsion spring.

FIG. 8 is an assembled, partially sectioned side view showing the movable handle according to the first preferred embodiment includes an elastic element in the form of a flat spring.

FIG. 9 is an assembled, partially sectioned side view showing the movable handle according to the first preferred embodiment includes an elastic element in the form of a coil spring.

FIG. 10 is an assembled, partially sectioned side view showing another variant of the movable handle according to the first preferred embodiment, in which the elastic element is also a flat spring.

FIG. 11 is an assembled, partially sectioned side view showing the movable handle according to a second preferred embodiment of the present invention.

FIG. 12 is a partially sectioned front view of the movable handle according to the second preferred embodiment as shown in FIG. 11.

FIG. 13 is an assembled, partially sectioned side view showing a movable member of the movable handle of FIG. 11 is moved.

FIG. 14 is a first partially sectioned top view showing the movable member of the movable handle of FIG. 11 is moved to cause moving of a second object.

FIG. 15 is a second partially sectioned top view showing the movable member of the movable handle of FIG. 11 is moved to cause moving of a second object.

FIG. 16 is a perspective view showing the movable handle according to a third preferred embodiment of the present invention in use.

FIG. 17 is a perspective view of the movable handle according to the third preferred embodiment of the present invention.

FIG. 18 is a cutaway view of the movable handle according to the third preferred embodiment as shown in FIG. 17.

FIG. 19 is a cutaway view showing a movable member of the movable handle of FIG. 17 is moved.

FIG. 20 is a fragmentary, enlarged cutaway view of the movable handle according to the third preferred embodiment as shown in FIG. 17.

FIG. 21 shows a working rod and a working section of the movable handle according to the third preferred embodiment as shown in FIG. 17.

FIG. 22 is a sectioned side view of the movable handle according to a fourth preferred embodiment of the present invention.

FIG. 23 is a rear view of the movable handle according to the fourth preferred embodiment as shown in FIG. 22.

FIG. 24 is a fragmentary, exploded perspective view showing an actuation portion and a corresponding movable member of the movable handle according to the fourth preferred embodiment as shown in FIG. 22.

FIG. 25 is an assembled sectioned side view showing the operation of the movable handle according to the fourth preferred embodiment as shown in FIG. 22.

FIG. 26 is a sectioned side view of the movable handle according to a fifth preferred embodiment of the present invention.

FIG. 27 is a fragmentary, exploded perspective view showing an actuation portion and a corresponding movable member of the movable handle according to the fifth preferred embodiment as shown in FIG. 26.

FIG. 28 is a sectioned side view of the movable handle according to a sixth preferred embodiment of the present invention.

FIG. 29 is a rear view of the movable handle according to the sixth preferred embodiment as shown in FIG. 28.

FIG. 30 is a fragmentary, exploded perspective view showing an actuation portion and a corresponding movable member of the movable handle according to the sixth preferred embodiment as shown in FIG. 28.

FIG. 31 is an assembled sectioned side view showing the operation of the movable handle according to the sixth preferred embodiment as shown in FIG. 28.

FIG. 32 is a sectioned side view of the movable handle according to a seventh preferred embodiment of the present invention.

FIG. 33 is a rear view of the movable handle according to the seventh preferred embodiment as shown in FIG. 32.

FIG. 34 is a fragmentary, exploded perspective view showing an actuation portion and a corresponding movable member of the movable handle according to the seventh preferred embodiment as shown in FIG. 32.

FIG. 35 is an assembled sectioned side view showing the operation of the movable handle according to the seventh preferred embodiment as shown in FIG. 32.

FIG. 36 is a first sectioned side view showing the movable handle according to an eighth preferred embodiment of the present invention.

FIG. 37 is a second sectioned side view of the movable handle according to the eighth preferred embodiment of the present invention showing the operation thereof.

FIG. 38 is a third sectioned side view of the movable handle according to the eighth preferred embodiment of the present invention showing the operation thereof.

FIG. 39 is a fourth sectioned side view of the movable handle according to the eighth preferred embodiment of the present invention showing the operation thereof.

FIG. 40 shows the operation of a working section of the movable handle according to the eighth preferred embodiment of the present invention.

FIG. 41 shows the working section of the movable handle of FIG. 40 drives a switch of a slide rail.

FIG. 42 is a sectioned side view of the movable handle according to a ninth preferred embodiment of the present invention.

FIG. 43 is an exploded perspective view of the movable handle according to a tenth preferred embodiment of the present invention.

FIG. 44 is an exploded perspective view of another perspective of the movable handle according to the tenth preferred embodiment of the present invention.

FIG. 45 is a schematic diagram of a locking portion pushing portion of the movable handle according to the tenth preferred embodiment of the present invention.

FIG. 46 is a schematic diagram of another perspective of a locking portion pushing portion of the movable handle according to the tenth preferred embodiment of the present invention.

FIG. 47 is a schematic diagram of another perspective of a locking portion pushing portion of the movable handle according to the tenth preferred embodiment of the present invention.

FIG. 48 is a schematic diagram according to the tenth preferred embodiment of the present invention in use.

FIG. 49 is a schematic diagram of a locking portion pushing portion of the movable handle according to an eleventh preferred embodiment of the present invention.

FIG. 50 is a schematic diagram of a locking portion pushing portion of the movable handle according to a twelfth preferred embodiment of the present invention.

FIG. 51 is a schematic diagram of a locking portion pushing portion of the movable handle according to a thirteenth preferred embodiment of the present invention.

FIG. 52 is a schematic diagram of a locking portion pushing portion of the movable handle according to a fourteenth preferred embodiment of the present invention.

FIG. 53 is a first schematic diagram of the movable handle according to a fifteenth preferred embodiment of the present invention.

FIG. 54 is a second schematic diagram of the movable handle according to the fifteenth preferred embodiment of the present invention.

FIG. 55 is a schematic diagram of the movable handle according to a sixteenth preferred embodiment of the present invention.

FIG. 56 is an exploded perspective view of the movable handle according to the sixteenth preferred embodiment of the present invention.

FIG. 57 is a sectioned side view of the movable handle according to the sixteenth preferred embodiment of the present invention.

FIG. 58 is a schematic diagram of the movable handle according to the sixteenth preferred embodiment of the present invention in use.

FIG. 59 is a schematic diagram of the movable handle according to a seventeenth preferred embodiment of the present invention.

FIG. 60 is an exploded perspective view of the movable handle according to the seventeenth preferred embodiment of the present invention.

FIG. 61 is a first schematic diagram according to the seventeenth preferred embodiment of the present invention in use.

FIG. 62 is a second schematic diagram of the movable handle according to the seventeenth preferred embodiment of the present invention in use.

### DETAILED DESCRIPTION OF THE INVENTION

The present invention will now be described with some preferred embodiments thereof and by referring to the accompanying drawings. For the purpose of easy to understand, elements that are the same in the preferred embodiments are denoted by the same reference numerals.

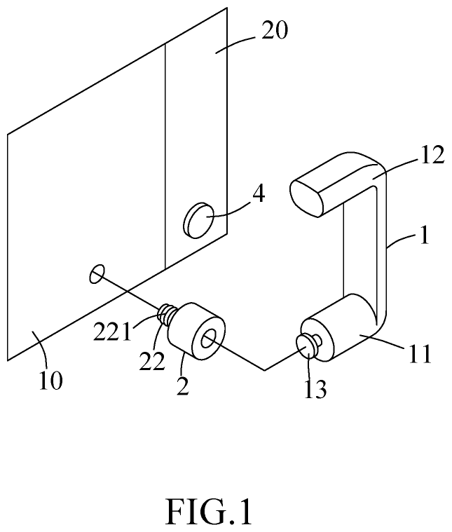

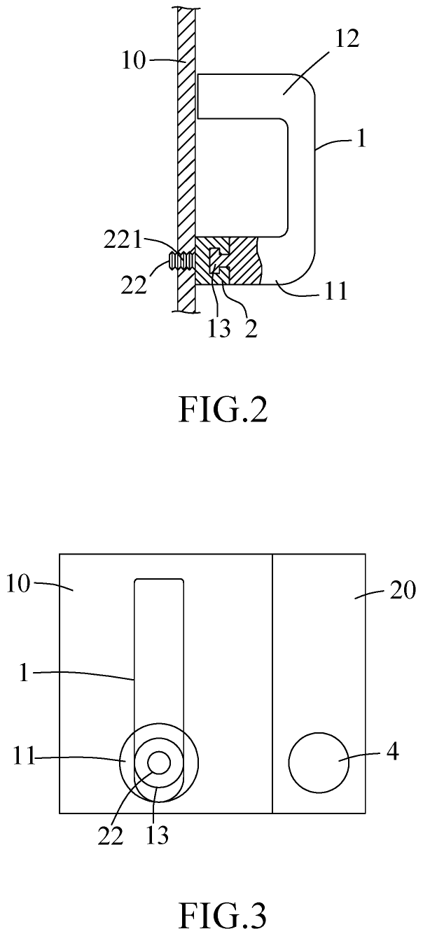

Refer to FIG. 1, FIG. 2 and FIG. 3, the movable handle of the present invention is provided. The movable handle of the first preferred embodiment includes a movable member 1 including a main body 11, and a seat 12, movably assembled to the main body 11 of the movable member 1, such that the movable member 1 is capable of moving.

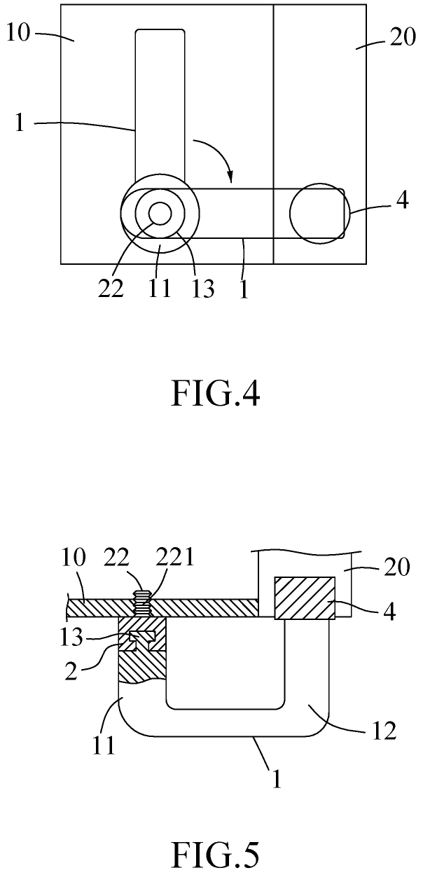

The movable member 1 is made of a plastic material, a metal material, or composite material. The movable member 1 may also be implemented with a bent portion 12. The main body 11 may be a column, a block, a sphere, a wedge, or other shape. The bent portion 12 can be bent inward, outward or in any direction. The seat 2 is made of a plastic material, metal material or composite material. The seat 2 and the main body 11 of the movable member 1 is movably assembled, such that the movable member 1 is capable of moving. The seat 2 is used to assembled to a first object 10, such that the movable member 1 can be assembled to the first object 10, such that the movable member 1 can be rotated on the first object 10 (as shown in FIG. 3 and FIG. 4), or moved upward, downward, leftward or rightward to implement the movable handle of the present invention.

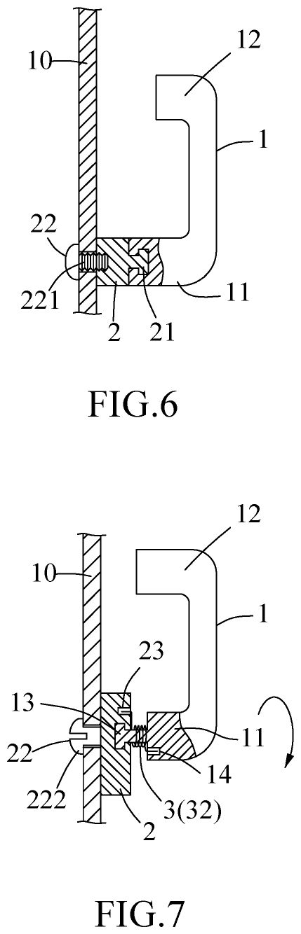

As shown in FIGS. 1 to 3, the movable member 1 preferably includes a first coupling section 13 for movably assembling to the seat 2. With the first coupling section 13 movably assembled to the seat 2, the movable member 1 can be turned, as shown in FIGS. 3 and 4, or moved upward and downward, or moved leftward and rightward relative to the seat 2 and the first object 10. Alternatively, as shown in FIG. 6, according to a variant of the first preferred embodiment, the seat 2 preferably includes a second coupling section 21, to which the main body 11 of the movable member 1 is movably assembled. With the main body 11 of the movable member 1 movably assembled to the second coupling section 21, the movable member 1 can also be turned, or moved upward and downward, or moved leftward and rightward relative to the seat 2 and the first object 10. The first coupling section 13 or the second coupling section 21 can be configured as a fastening section, a threaded section, a boss section, a female fastener, a male fastener, a protruded section, a recessed section, or a strip.

As shown in FIGS. 1 to 3, the seat 2 preferably includes a connecting section 22 for connecting to the first object 10, such that a screw fastening structure 221, as shown in FIGS. 2, 6 and 8, a snap-on fastening structure 222, as shown in FIG. 7, an expanded connection structure 223, as shown in FIG. 9, a riveting structure 224, as shown in FIG. 10, a welding structure, a glue-bonding structure or a magnetic fastening structure can be achieved between the connecting section 22 and the first object 10.

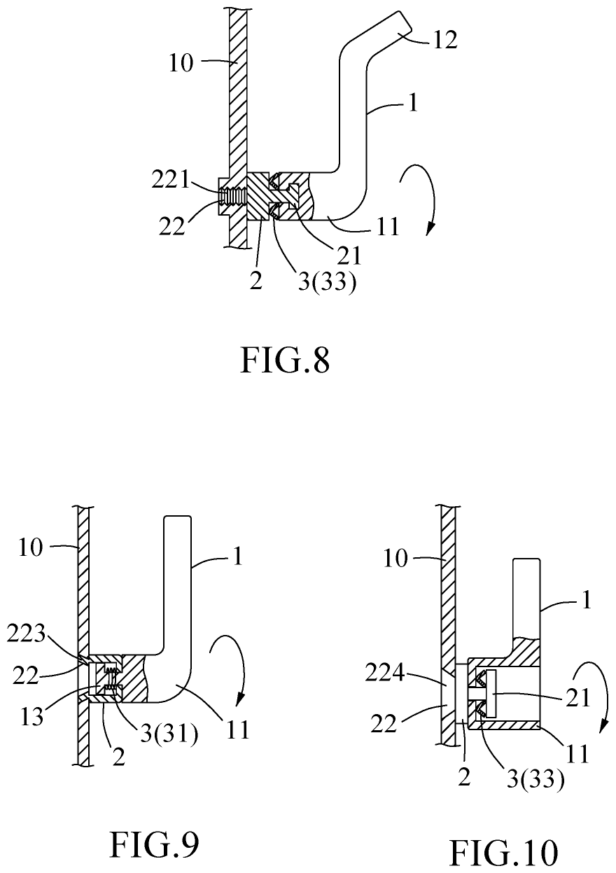

Please refer to FIGS. 7 to 10. In the first preferred embodiment, the movable handle preferably further includes an elastic element 3, which is preferably disposed between the main body 11 of the movable member 1 and the seat 2, such that the elastic element 3 has an end pushing against the main body 11 of the movable member 1 and another end pushing against the seat 2. More specifically, the elastic element 3 is fitted around the first coupling section 13 of the movable member 1 with one end pushing against the main body 11 of the movable member 1 and another end pushing against the seat 2. Alternatively, as shown in FIGS. 8 and 10, according to the variant of the first preferred embodiment of the present invention, the elastic element 3 is fitted around the second coupling section 21 with one end pushing against the main body 11 of the movable member 1 and another end pushing against the seat 2.

The elastic element 3 can be a coil spring 31, as shown in FIG. 9, a torsion spring 32, as shown in FIG. 7, a flat spring 33, as shown in FIGS. 8 and 10, or an elastic bar (not shown). Preferably, the elastic element 3 is a torsion spring 32 (see FIG. 7) capable of driving the movable member 1 to turn. More specifically, in the case the elastic element 3 used is a torsion spring as shown in FIG. 7, the main body 11 of the movable member 1 can include a first abutting section 14 and the seat 2 can include a second abutting section 23. The first abutting section 14 and the second abutting section 23 can be in the form of a hole or a boss. The elastic element 3 has one end interfered by the first abutting section 14 and another end interfered by the second abutting section 23. In the case the elastic element 3 used is a coil spring 31 (see FIG. 9) or a flat spring 33 (see FIGS. 8 and 10), the elastic element 3 can exert a spring force on the movable member 1 and therefore produces a frictional resistance between the movable member 1 and the seat 2 or the elastic element 3 when the movable member 1 is moved.

Referring back to FIGS. 1 to 3. When the movable member 1 is turned, moved upward or downward, or moved leftward or rightward, the bent portion 12 or some other portion of the movable member 1 is brought to actuate an actuator member 4 or some other intended member by, for example, pushing against it as shown in FIG. 5, so that the actuator member 4 or the intended member can actuate some intended function. The actuator member 4 or the intended member can be installed on a second object 20 or on the first object 10 to be functionally operable.

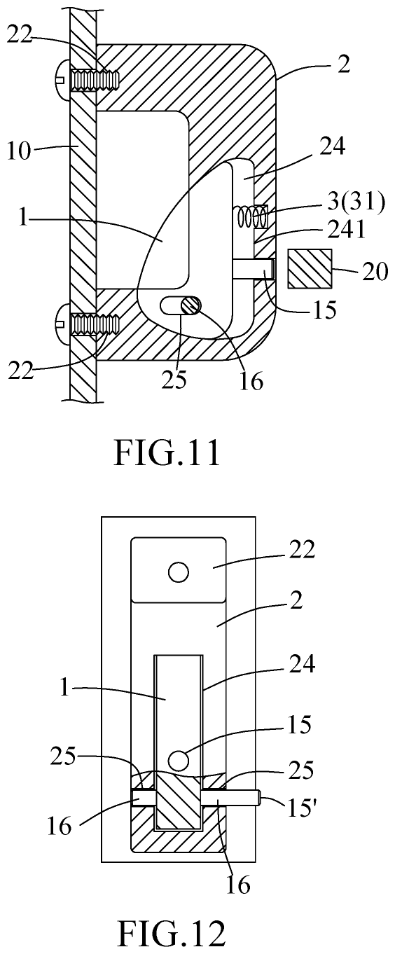

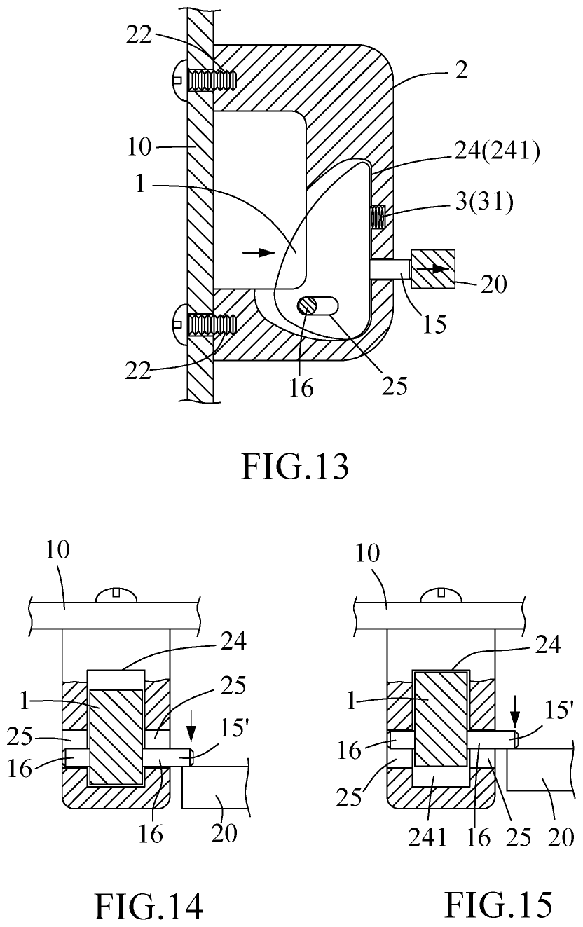

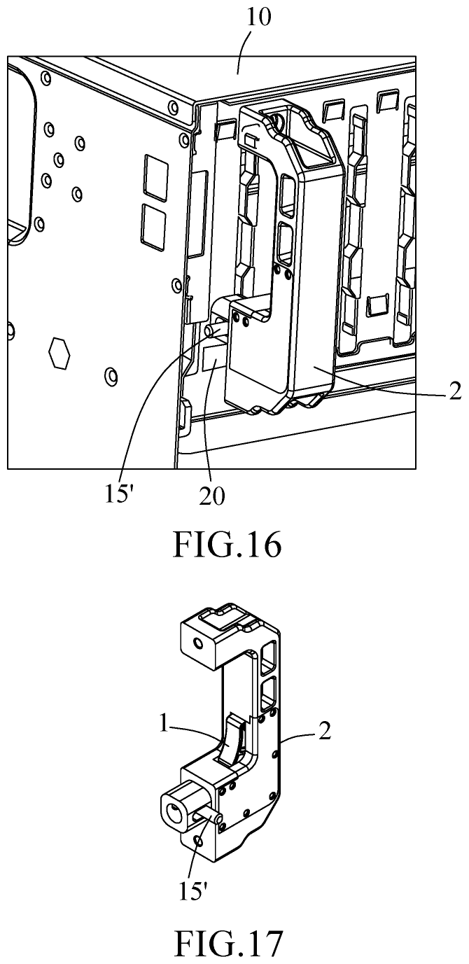

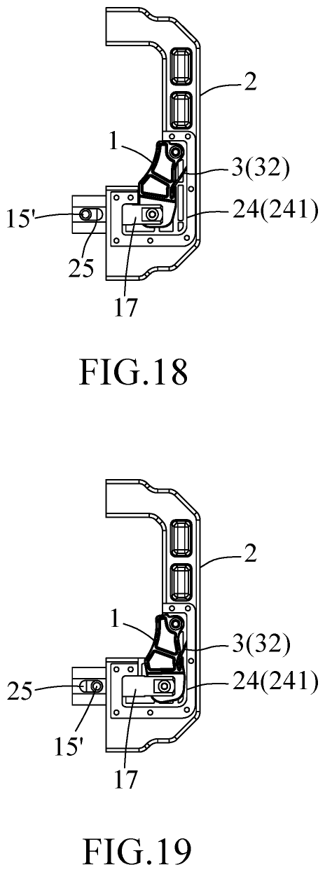

FIGS. 11 and 12 illustrate the movable handle according to a second preferred embodiment of the present invention; and FIGS. 16 to 18 illustrate the movable handle according to a third preferred embodiment of the present invention. As shown, both of the second and third embodiments include a movable member 1 and a seat 2. The movable member 1 is movably or pivotally assembled to the seat 2, so that the movable member 1 can be moved on and relative to the seat 2, as shown in FIGS. 13 and 19. Wherein, the seat 2 can be configured as a handle or any other intended shape, such as a lying U-shaped member, a straight bar-shaped member, or any other suitable shape. Further, a connecting section 22 is formed at one end or each of two ends of the seat 2 for connecting to a first object 10 by screw fastening, snap-on fastening, riveting, expanded connection, welding, glue bonding or magnetic fastening. The movable member 1 can be configured as a handle, a push key, a push button, a joystick, a block or any other suitable shape, so long as the movable member 1 can be movably assembled (see FIG. 12) or pivotally assembled (see FIG. 18) to the seat 2 for moving inside or outside the seat 2 to drive a second object 20 to move, as shown in FIGS. 13, 14 and 15.

As can be seen in FIGS. 11, 12 and 18, a selected side of the seat 2, such as an inner side thereof, can be provided with a cavity 24 or a hole, such that the movable member 1 is movably mounted or pivotally connected to the cavity 24 or the hole while a retraction space 241 is defined between the cavity 24 or the hole and the movable member 1, allowing the movable member 1 to move in the cavity 24 or the hole.

Further, the movable member 1 can be provided with a working section 15, 15′ that is movable inside the seat 2 or outside the seat 2. The working section 15, 15′ can be a rod, a post, a block, a ball or any other suitable form. The working section 15, 15′ can be assembled to or integrally formed on any side of the movable member 1, as shown in FIG. 11 or 12, to be movable inside or outside the seat 2. When the movable member 1 is operated and moved, the working section 15, 15′ is caused to move a second object 20, as shown in FIGS. 13, 14 and 15. Alternatively, as shown in FIGS. 18, 19 and 21, the working section 15′ can be associated with a working rod 17, which is pivotally connected to the movable member 1. Therefore, when the movable member 1 is operated and moved, the working rod 17 and the working section 15′ are caused to move at the same time.

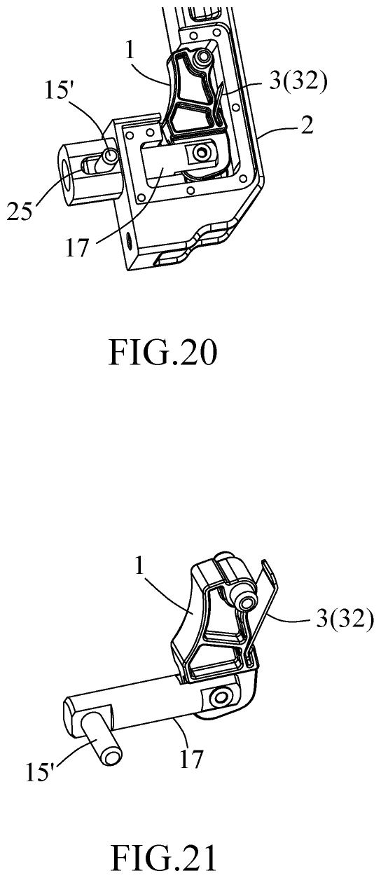

In the second preferred embodiment shown in FIGS. 11 and 12, as well as in the third preferred embodiment shown in FIGS. 18, 20 and 21, the movable handle can further include an elastic element 3. The elastic element 3 can be disposed inside or outside the cavity 24, and can be a coil spring 31, a torsion spring 32 or a flat spring 33, as shown in FIGS. 19 and 21. Or, the elastic element 3 can be an elastic bar (not shown). The elastic element 3 has an end pushing against the movable member 1 and another end pushing against the seat 2. With these arrangements, the elastic element 3 can exert a spring force on the operated movable member 1 for the same to return to its original position or to do other actions.

Again, as shown in FIGS. 11 and 12, the movable member 1 in the second preferred embodiment can include an interfering section 16 movably assembled to the seat 2. The interfering section 16 can be a rod, a post, a block, a ball or any other suitable form. The interfering section 16 can be assembled to or integrally formed with the movable member 1. In an operable embodiment, the interfering section 16 can also be extended beyond the working section 15′, so that the working section 15′ is movable inside or outside the seat 2 and can be caused to move a second object 20, as shown in FIGS. 13 to 15. Meanwhile, the seat 2 in the second preferred embodiment can include an elongated slot 25 or an elongated hole, such that the interfering section 16 and the working section 15′ are movable only within a range defined by the elongated slot 25 or the elongated hole.

In the second preferred embodiment that includes the interfering section 16, the movable handle can also further include an elastic element 3. The elastic element 3 can be a coil spring 31, a torsion spring 32, a flat spring 33 or an elastic bar. The elastic element 3 has an end pushing against the movable member 1 and another end pushing against the seat 2. The elastic element 3 can exert a spring force on the operated movable member 1 for the same to return to its original position or to do other actions.

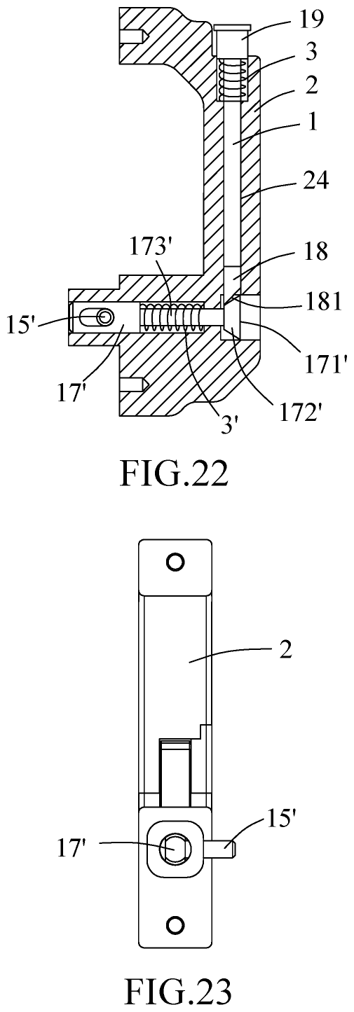

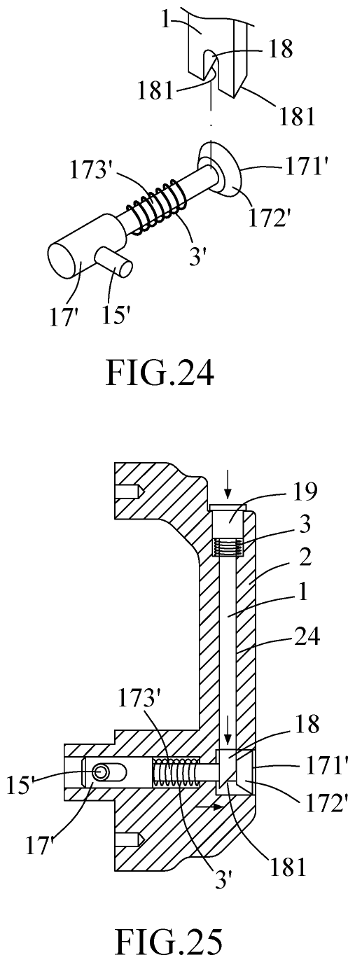

FIGS. 22, 23 and 24 illustrate the movable handle according to a fourth preferred embodiment of the present invention. As shown, in the fourth preferred embodiment, the movable handle also includes a movable member 1 and a seat 2. The seat 2 in the fourth preferred embodiment is structurally similar to those in the second and third embodiments and includes a cavity 24. The movable member 1 is linearly movably disposed in the cavity 24 of the seat 2. An end of the movable member 1 has an actuation portion 18 for causing another member to move and a corresponding movable member 17 that can be moved accordingly, and an opposite end of the movable member 1 has an operation portion 19 for operating the actuation portion 18 and accordingly driving the corresponding movable member 17′ via the actuation portion 18. More specifically, the actuation portion 18 of the movable member 1 can drive the corresponding movable member 17′ at a head portion 171′ or a shank portion 173′ thereof to move the corresponding movable member 17′. The actuation portion 18 has a bevel surface 181 and the head portion 171′ has a bevel surface 172′, such that the bevel surface 181 of the actuation portion 18 pushes against the bevel surface 172′ of the head portion 171′. In other operable embodiments, the actuation portion 18 and the head portion 171′ can respectively have a cambered surface or a curved surface. With the above arrangements of the fourth preferred embodiment, the corresponding movable member 17′ can cause a working section 15′ to move. More specifically, the movable member 1 or the corresponding movable member 17′ can cause the working section 15′ to move by a distance ranged between 0.5 mm and 500 mm. Further, the corresponding movable member 17′ and the working section 15′ can be integrally formed or be assembled to each other.

As can be seen in FIGS. 22 and 25, the movable handle in the fourth preferred embodiment can further include an elastic element 3, which has an end pushing against the operation portion 19 of the movable member 1 and another end pushing against the cavity 24 of the seat 2 for elastically pushing the moved movable member 1 back to its original position; and another elastic element 3′, which has an end pushing against the seat 2 and another end pushing against the corresponding movable member 17′ for elastically pushing the moved corresponding movable member 17′ back to its original position.

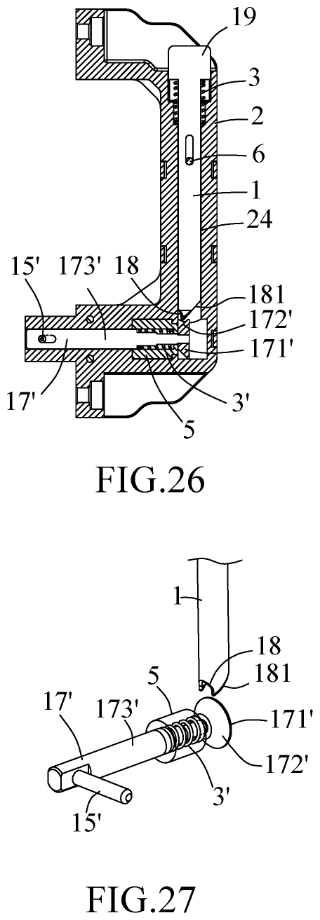

FIGS. 26 and 27 illustrate the movable handle according to a fifth preferred embodiment of the present invention. As shown, the movable handle in the fifth preferred embodiment is structurally similar to the fourth preferred embodiment but further includes a sleeve 5 fitted around the elastic element 3′ to limit the range within which the elastic element 3′ can move.

As can be seen in FIG. 26, the movable handle in the fifth preferred embodiment further includes a limiting element 6, which is fixed to the seat 2 to extend through the movable member 1 or the corresponding movable member 17′ to limit the maximum moving distance allowed for the movable member 1 or the corresponding movable member 17′.

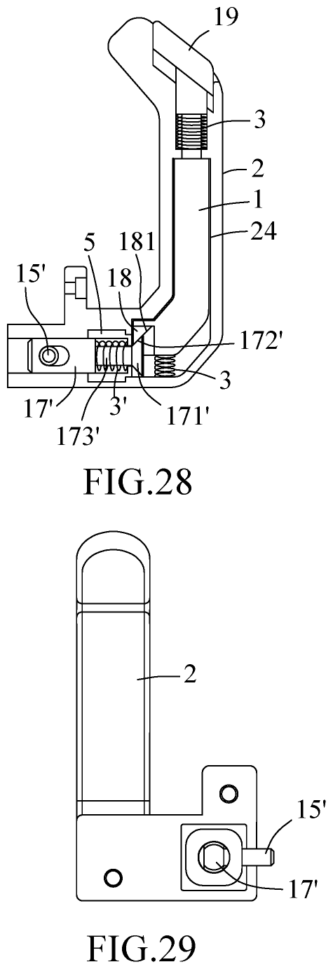

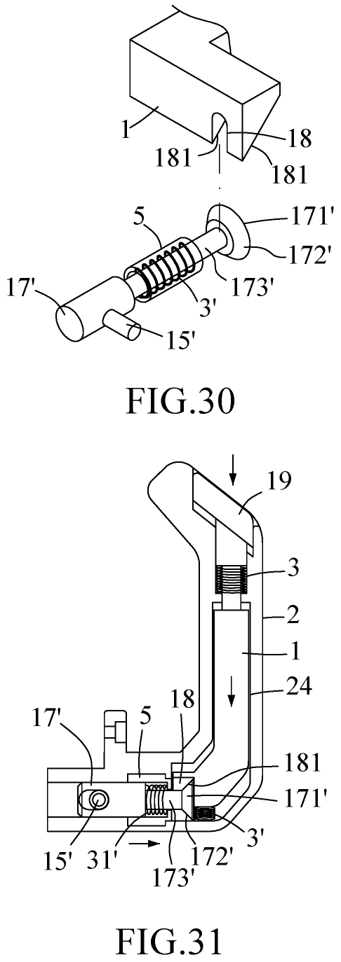

FIGS. 28, 29 and 30 illustrate the movable handle according to a sixth preferred embodiment of the present invention. As shown, the movable handle in the sixth preferred embodiment also includes a movable member 1 and a seat 2. The seat 2 in the sixth preferred embodiment is structurally similar to those in the second and third embodiments and includes a cavity 24. The movable member 1 is linearly movably disposed in the cavity 24 of the seat 2 and includes a bend. An end of the movable member 1 has an actuation portion 18 for causing another member to move and a corresponding movable member 17 that can be moved accordingly, and an opposite end of the movable member has an operation portion 19 for operating the actuation portion 18 and accordingly driving the corresponding movable member 17′ via the actuation portion 18. More specifically, the actuation portion 18 of the movable member 1 can drive the corresponding movable member 17′ at a head portion 171′ thereof to move the corresponding movable member 17′. The actuation portion 18 has a bevel surface 181 and/or the head portion 171′ has a bevel surface 172′, such that the bevel surface 181 of the actuation portion 18 can push against the bevel surface 172′ of the head portion 171′. With the above arrangements of the sixth preferred embodiment, the corresponding movable member 17′ can cause a working section 15′ to move. More specifically, the movable member 1 or the corresponding movable member 17′ can cause the working section 15′ to move by a distance ranged between 0.5 mm and 500 mm.

As can be seen in FIGS. 28 and 31, the movable handle in the sixth preferred embodiment can further include an elastic element 3, which has an end pushing against the operation portion 19 of the movable member 1 and another end pushing against the cavity 24 of the seat 2 for elastically pushing the moved movable member 1 back to its original position; and another elastic element 3′, which has an end pushing against the seat 2 and another end pushing against the corresponding movable member 17′ for elastically pushing the moved corresponding movable member 17′ back to its original position.

Further, the movable handle in the sixth preferred embodiment also includes a sleeve 5 fitted around the second elastic element 3′ to limit the range within which the second elastic element 3′ can move.

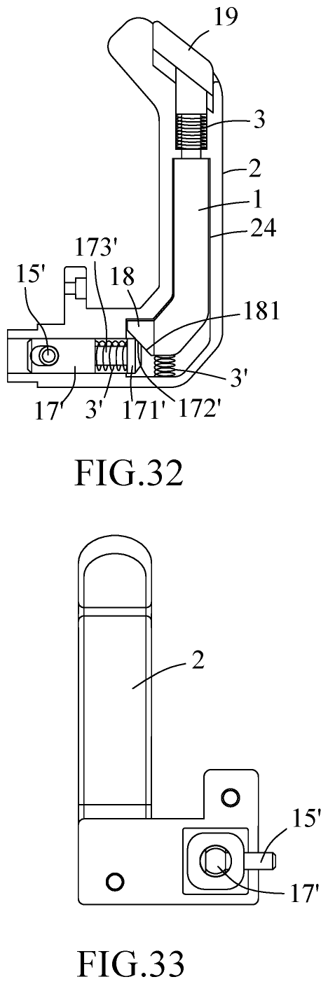

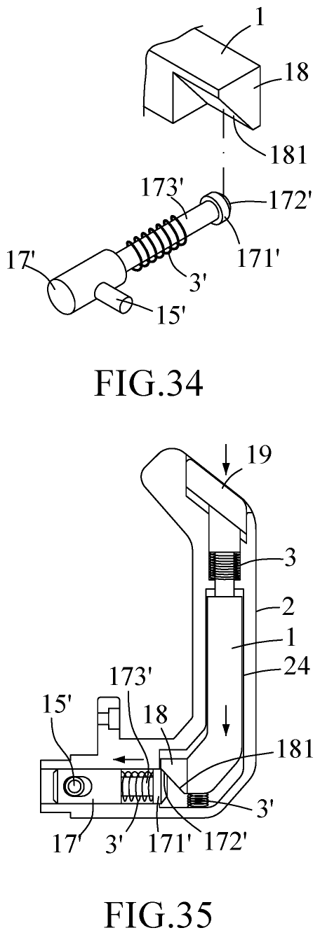

FIGS. 32, 33 and 34 illustrate the movable handle according to a seventh preferred embodiment of the present invention. As shown, the movable handle in the seventh preferred embodiment also includes a movable member 1 and a seat 2. The seat 2 in the seventh preferred embodiment is structurally similar to that in the sixth embodiment and includes a cavity 24. The movable member 1 is linearly movably disposed in the cavity 24 of the seat 2 and includes a bend. An end of the movable member 1 has an actuation portion 18 for causing another member to move and a corresponding movable member that can be moved correspondingly, and an opposite end of the movable member has an operation portion 19 for operating the actuation portion 18 and accordingly driving the corresponding movable member 17′ via the actuation portion 18. The actuation portion 18 can be in the form of a cavity, a hole, a flat surface, a cambered surface, a curved surface, a protrusion or a recess. More specifically, the actuation portion 18 of the movable member 1 can drive the corresponding movable member 17′ at a head portion 171′ thereof to move the corresponding movable member 17′. The actuation portion 18 has a bevel surface 181 and/or the head portion 171′ has a bevel surface 172′, such that the bevel surface 181 of the actuation portion 18 can push against the bevel surface 172′ of the head portion 171′. With the above arrangements of the seventh preferred embodiment, the corresponding movable member 17′ can cause a working section 15′ to move. More specifically, the movable member 1 or the corresponding movable member 17′ can cause the working section 15′ to move by a distance ranged between 0.5 mm and 500 mm.

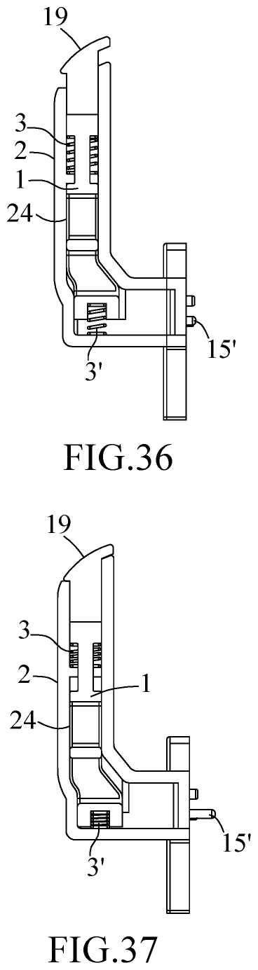

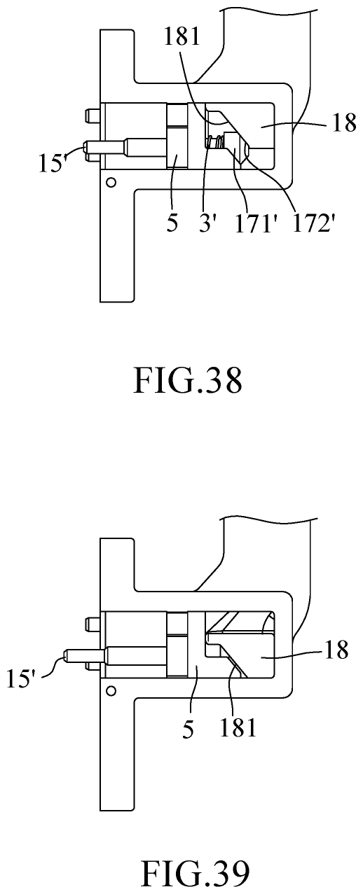

As can be seen in FIGS. 32 and 35, the movable handle in the seventh preferred embodiment can further include an elastic element 3, which has an end pushing against the operation portion 19 of the movable member 1 and another end pushing against the cavity 24 of the seat 2 for elastically pushing the moved movable member 1 back to its original position; and another elastic element 3′, which has one end pushing against the seat 2 and another end pushing against the corresponding movable member 17′ for elastically pushing the moved corresponding movable member 17′ back to its original position. Please refer to FIGS. 36 to 39. According to an eighth preferred embodiment of the present invention, the movable handle has a working section 15′, which can be moved to protrude from or retract into the seat 2.

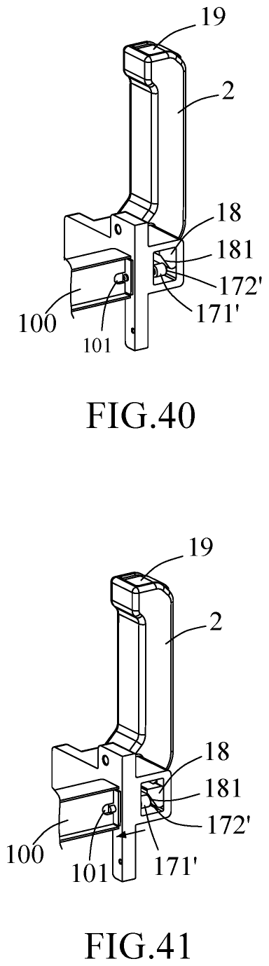

As shown in FIGS. 40 and 41, in the eighth preferred embodiment, the working section 15′ can be coaxial with the corresponding movable member 17′. And, when the working section 15′ is moved, it can drive a switch 101 of a slide rail 100 to move.

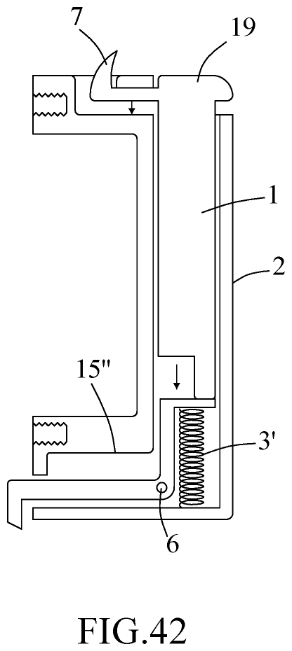

Please refer to FIG. 42. The movable handle according to a ninth preferred embodiment of the present invention further includes a retaining member 7 and a working section 15″. In the ninth embodiment, the movable member 1 is vertically movably assembled to the seat 2 and has a top serving as an operation portion 19. The retaining member 7 has some elasticity and is horizontally connected to or pressed against the operation portion 19. The working section 15″ has a first horizontal end that is exposed from the seat 2 and can be hook-shaped, and a second horizontal end that is pressed against or interfering with a bottom of the movable member 1. A point of the working section 15″ located between the first and the second horizontal end is pivotally connected to the seat 2 via a limiting element 6, which is provided to limit the range within which the movable member 1 can be moved. The movable handle in the ninth embodiment further includes an elastic element 3′, which has an end pushing against the second horizontal end of the working section 15″ and another end pushed against the seat 2. When the operation portion 19 of the movable member 1 is downward pushed, the retaining member 6 is caused to retract into the seat 2, and the bottom of the movable member 1 in contact with the second horizontal end of the working section 15″ compresses the elastic element 3′ to simultaneously upward move the first horizontal end of the working section 15″. When the operation portion 19 of the movable member 1 is released from the downward push, the retaining member 7, the movable member 1, the elastic element 3′ and the working section 15″ all return to their respective original position due to an elastic restoring force of the elastic element 3′.

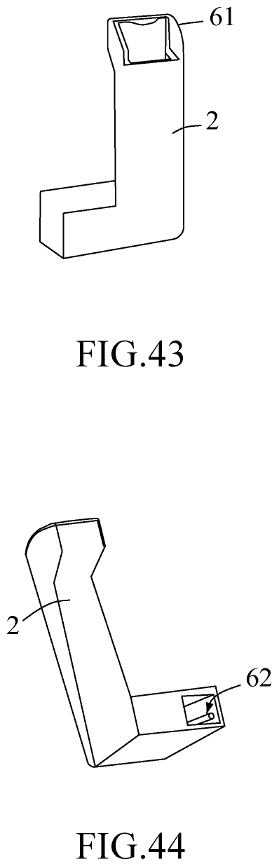

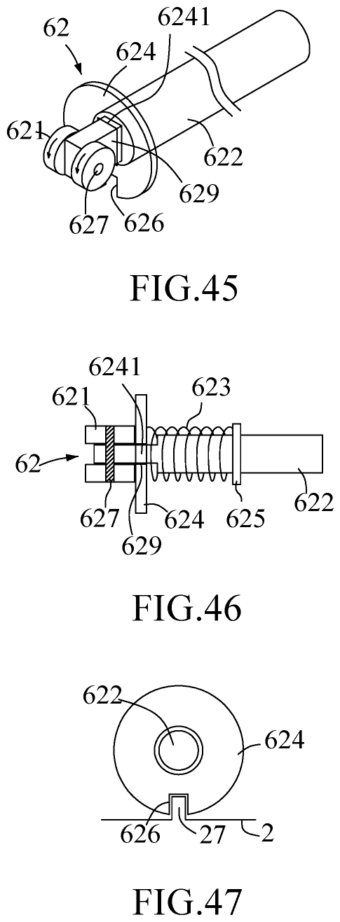

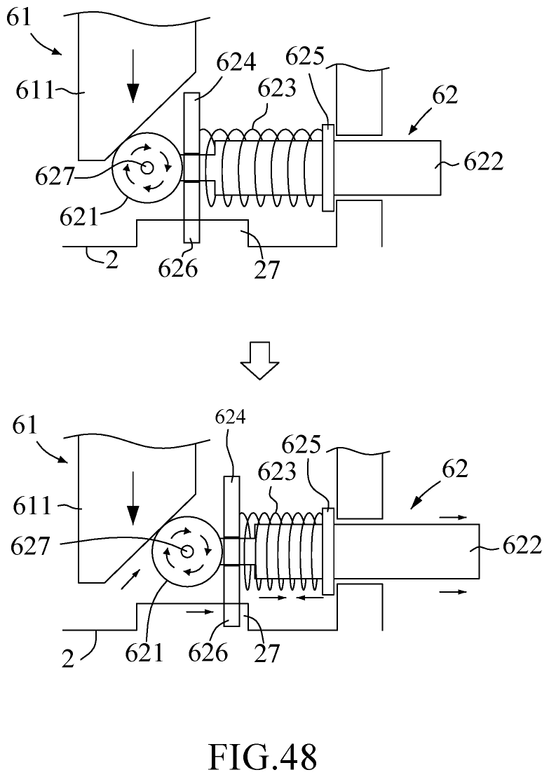

As shown in FIGS. 43 to 48, in the tenth preferred embodiment, the movable member 1 includes an operation portion 61 and a pushing portion 62. The operation portion 61 is movably mounted on the seat 2. The pushing portion 62 is movably mounted on the operation portion 61. The operation portion 61 controls the pushing portion 62 to extend out of the seat 2 to form a pushed-out state, or the operation portion 61 controls the pushing portion 62 to move to the seat 2 to form a retracted state.

In this embodiment, one end of the operation portion 61 includes a pusher portion 611, and one end of the pushing portion 62 includes an abutting portion 621. The pusher portion 611 abuts against the abutting portion 621, and the pusher portion 611 of the operation portion 61 controls the pusher portion 611 of the pushing portion 62, such that the pushing portion 62 extends out of the seat 2 to form a pushed-out state, or the operation portion 61 controls the pushing portion 62 to move to the seat 2 to form a retracted state.

In a preferred embodiment of the present invention, the pushing portion 62 includes a rod body 622. The abutting portion 621 is mounted at one end of the rod body 622. The rod body 622 is sleeved with an elastic element 623 and includes two blocking portions 624 and 625. The blocking portions 624 and 625 abut against the two ends of the elastic element 623 respectively. One of the blocking portions 624 includes a limiting portion 626. The seat 2 includes a corresponding limiting portion 27 connecting to the limiting portion 626, and the blocking portion 624 includes an anti-rotation portion 6241. The pushing portion 62 includes a corresponding anti-rotation portion 629 for anti-rotating correspondingly, preventing the abutting portion 621 (such as a rolling body) of the pushing portion 62 from rotating during movement. The pusher portion 611 may be an inclined body or a rolling body, and the abutting portion 621 may be a rolling body or an inclined body, and the rolling body may be a unidirectional wheel. In this embodiment, the pusher portion 611 is an inclined body, the abutting portion 621 is a rolling body, and the abutting portion 621 is mounted at one end of the rod body 622 with a bolt 627.

In this way, the pusher portion 611 of the operation portion 61 pushes the pusher portion 611 of the pushing portion 62, so that the rod body 622 of the pushing portion 62 extends out of the seat 2 to form a pushed-out state, or the operation portion 61 controls the rod body 622 of the pushing portion 62 to move to the seat 2 to form a retracted state. When the pushing portion 62 is moving, the limiting portion 626 can cooperate with the corresponding limiting portion 27 to limit the pushing portion 62 to achieve the effect of stable movement.

Please refer to FIG. 26 and FIG. 27, in this embodiment, two elastic elements 3 and 623 are provided. One end of the elastic element 3 abuts against the main body 11 and the other end abuts against the seat 2. One end of the other elastic element 3′ abuts against the pushing portion 62, and the other end abuts against the seat 2.

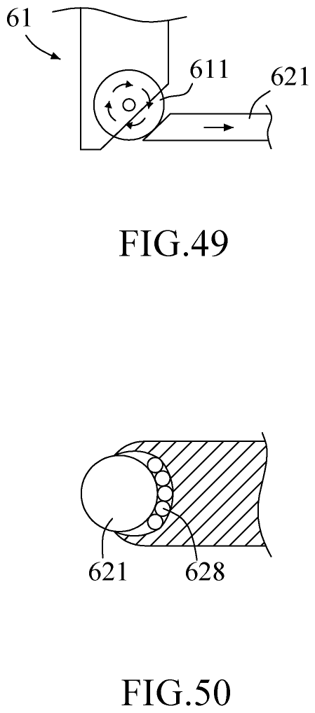

As shown in FIG. 49 and FIG. 50, in the eleventh embodiment of the present invention, the pusher portion 611 is a rolling body, and the abutting portion 621 is an inclined body. In this way, the pusher portion 611 abuts against the abutting portion 621, and the pusher portion 611 of the operation portion 61 controls the pusher portion 611 of the pushing portion 62, such that the pushing portion 62 extends out of the seat 2 to form a pushed-out state, or the operation portion 61 controls the pushing portion 62 to move to the seat 2 to form a retracted state. In addition, in the twelfth embodiment of the present invention, the abutting portion 621 may have a rolling body and several second rolling bodies 628. For example, it may be a rolling module formed by a universal ball, a large universal ball or several small universal balls. In this way, the abutting portion 621 may cooperate with the second rolling body 628 to reduce friction and achieve the effect of easy driving.

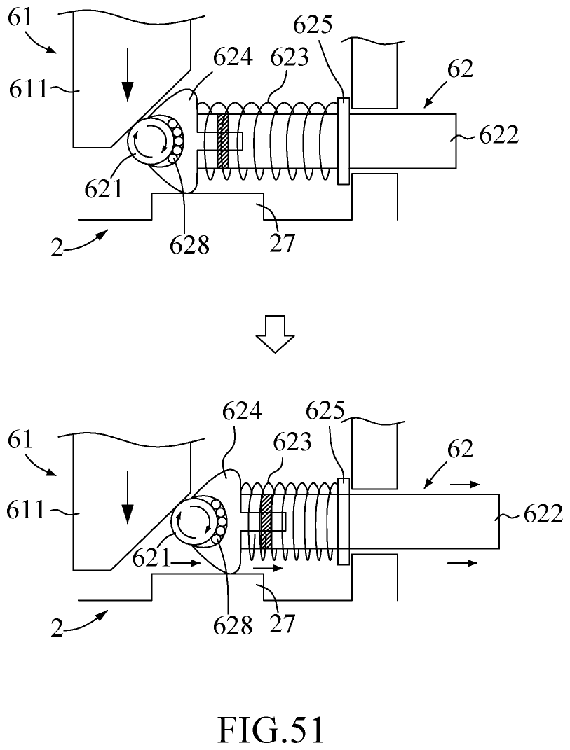

As shown in FIG. 51, in the thirteenth embodiment of the present invention, the abutting portion 621 may include a rolling body and several second rolling bodies 628. For example, a rolling module formed by a large universal ball and several small universal balls. In this way, the pusher portion 611 of the operation portion 61 pushes the pusher portion 611 of the pushing portion 62, such that the rod body 622 of the pushing portion 62 extends out of the seat 2 to form a pushed-out state, or the operation portion 61 controls the rod body 622 of the pushing portion 62 to move to the seat 2 to form a retracted state. When the pushing portion 62 is moving, the limiting portion 626 may cooperate with the corresponding limiting portion 27 to limit the pushing portion 62 to achieve the effect of stable movement, and the abutting portion 621 may cooperate with the second rolling body 628 to reduce the friction and achieve the effect of easy driving.

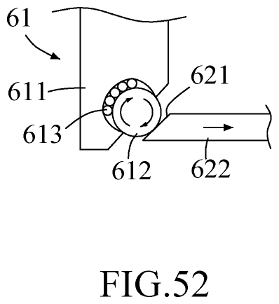

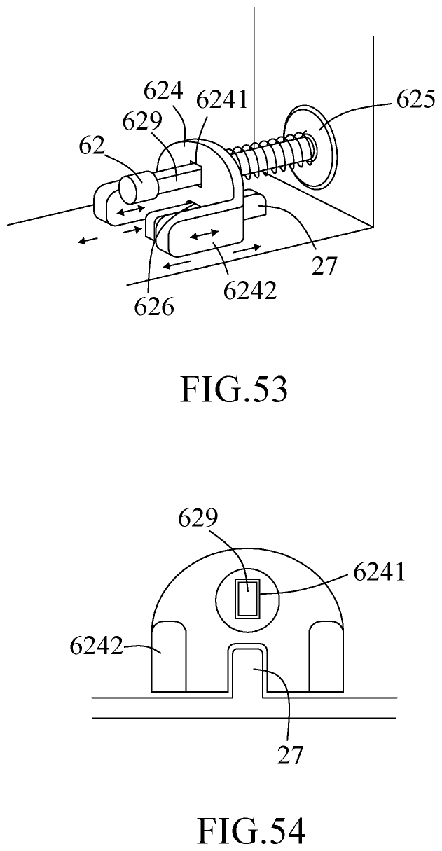

As shown in FIG. 52, in the fourteenth embodiment of the present invention, the pushing portion 611 may include a first rolling body 612 and several second rolling bodies 613. For example, a rolling module formed by a large universal ball and several small universal balls. The abutting portion 621 is an inclined body. In this way, the pusher portion 611 abuts against the abutting portion 621 by the first rolling body 612, such that the first rolling body 612 may cooperate with each of the second rolling bodies 613 to reduce friction and achieve the effect of easy driving.

As shown in FIG. 53 and FIG. 54, in the fifteenth embodiment of the present invention, the pushing portion 62 includes a rod body 622 having a blocking portion 624. The blocking portion 624 includes a sliding portion 6242 for correspondingly sliding to abut against the seat 2, so as to achieve the effect of limiting.

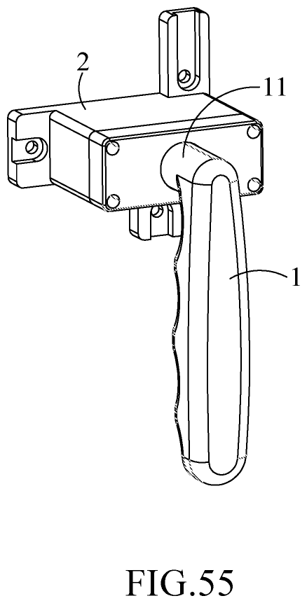

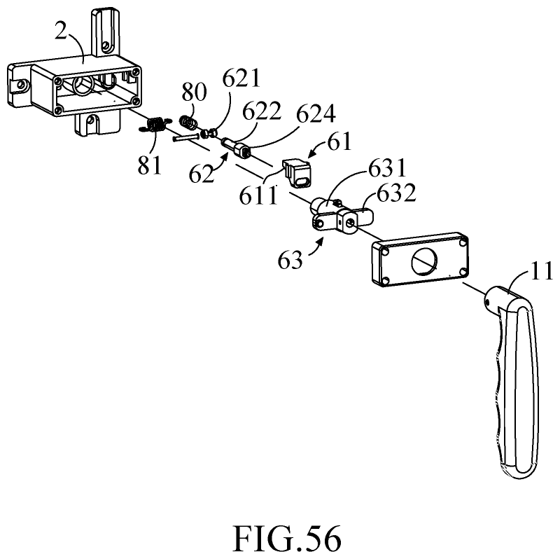

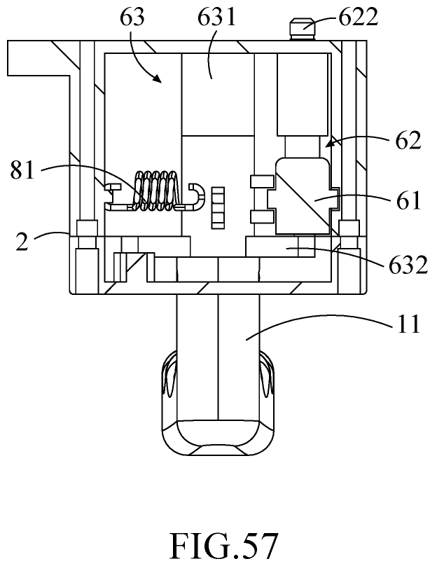

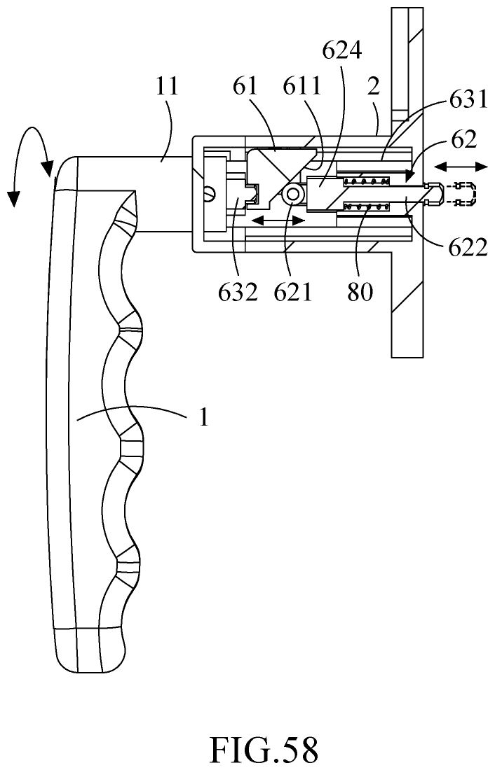

As shown in FIG. 55 to FIG. 58, in the sixteenth embodiment of the present invention, the seat 2 and the main body 11 of the movable member 1 is movably assembled, such that the movable member 1 is capable of moving. The movable member 1 includes an operation portion 61, a pushing portion 62 and a driving portion 63. The operation portion 61 is movably mounted on the seat 2. The pushing portion 62 is movably mounted on the operation portion 61. The driving portion 63 is connected to the main body 11 and the operation portion 61. The driving portion 63 may drive the operation portion 61, such that the operation portion 61 may control the pushing portion 62 to extend out of the seat 2 to form a pushed-out state, or the operation portion 61 may control the pushing portion 62 to move to the seat 2 to form a retracted state.

In this embodiment, one end of the operation portion 61 includes a pusher portion 611, the pusher portion 62 includes a rod body 622, one end of the rod body 622 includes an abutting portion 621, and the pusher portion 611 abuts against the abutting portion 621. The pusher portion 611 may be an inclined body, and the abutting portion 621 may be a rolling body. In this way, the movable member 1 may be rotated in one direction, and the pusher portion 611 of the operation portion 61 pushes the abutting portion 621 of the pushing portion 62, such that the rod body 622 of the pushing portion 62 extends out of the seat 2 to form a pushed-out state, or the movable member 1 may be rotated in another direction, and the operation portion 61 may control the rod body 622 of the pushing portion 62 to move to the seat 2 to form a retracted state.

In addition, the pusher portion 611 of the operation portion 61 may be a rolling body, and the abutting portion 621 may be an inclined body (not shown), so that the present invention can better meet the requirements of practical use.

In this embodiment, the rod body 622 is sleeved with a first elastic element 80 and includes a blocking portion 624. One end of the first elastic element 80 abuts against the seat 2, and the other end of the first elastic element 80 abuts against the blocking portion 624. In this way, the first elastic element 80 can be compressed at the same time when the rod body 622 of the pushing portion 62 extends out of the seat 2 to form a pushed-out state, and the first elastic element 80 is released at the same time when the rod body 622 of the pushing portion 62 moves to the seat 2 to form a retracted state, thereby increasing the stability and convenience during operation.

In this embodiment, the driving portion 63 includes a rotating shaft 631 and a driving member 632. The rotating shaft 631 is movably mounted on the seat 2 and connected to the main body 11, and the driving member 632 is mounted on the rotating shaft 631 and connected to the operation portion 61. In this way, the movable member 1 can be rotated to cause the main body 11 to interlock with the rotating shaft 631 of the driving portion 63, the driving member 632 is driven at the same time, and the driving member 632 of the driving portion 63 may drive the operation portion 61, such that the operation portion 61 may control the pushing portion 62 to extend out of the seat 2 to form a pushed-out state, or the operation portion 61 may control the pushing portion 62 to move to the seat 2 to form a retracted state.

In this embodiment, a second elastic element 81 is further provided and it may be a tension spring. One end of the second elastic element 81 is connected to the seat 2, and the other end of the two elastic members 81 is connected to the rotating shaft 631. In this way, when the movable member 1 is rotated in one direction to cause the main body 11 to interlock with the rotating shaft 631 of the driving portion 63, the rotating shaft 631 stretches the second elastic member 81; when the movable member 1 is rotated in the other direction to cause the main body 11 to interlock with the rotating shaft 631 of the driving portion 63, the second elastic element 81 is in a contracted state, thereby increasing stability and convenience during operation.

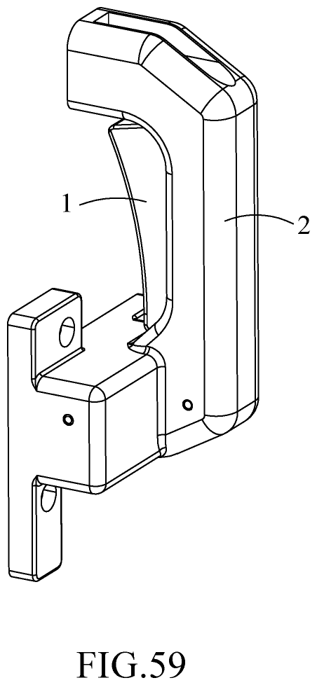

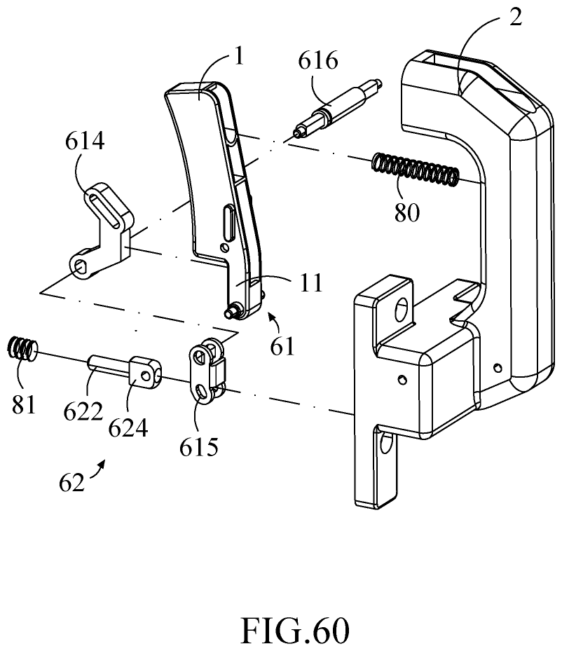

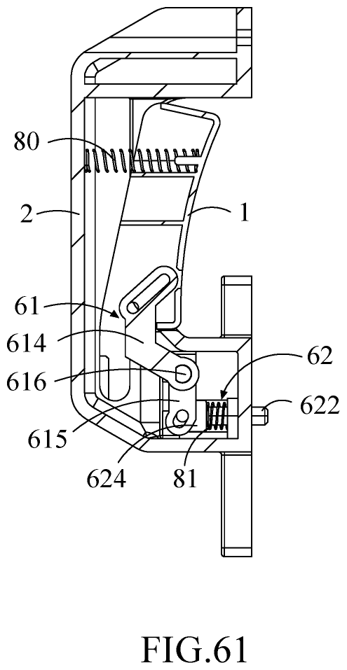

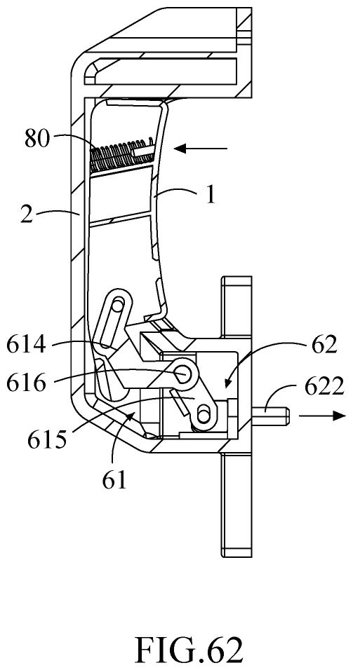

As shown in FIG. 59 to FIG. 62, in the seventeenth embodiment of the present invention, the seat 2 and the main body 11 of the movable member 1 is movably assembled, such that the movable member 1 is capable of moving. The movable member 1 includes an operation portion 61 and a pushing portion 62. The operation portion 61 is movably mounted on the seat 2. The pushing portion 62 is movably mounted on the operation portion 61. The operation portion 61 controls the pushing portion 62 to extend out of the seat 2 to form a pushed-out state, or the operation portion 61 controls the pushing portion 62 to move to the seat to form a retracted state.

In this embodiment, the operation portion 61 includes a tie rod 614, a connecting rod 615, and a shaft body 616. The tie rod 614 is movably connected to the movable member 1, the shaft body 616 is movably mounted on the seat 2 and connected to the tie rod 614 and the connecting rod 615, and the connecting rod 615 is movably connected to the pushing portion 62. The pushing portion 62 includes a rod body 622, and one end of the rod body 622 includes a blocking portion 624. In this way, the movable member 1 can be pressed to cause the tie rod 614 and the connecting rod 615 of the operation portion 61 to push the pushing portion 62, such that the rod body 622 of the pushing portion 62 extends out of the seat 2 to form a pushed-out state, or release the movable member 1, such that the operation portion 61 controls the rod body 622 of the pushing portion 62 to move to the seat 2 to form a retracted state.

In this embodiment, a first elastic element 80 is mounted between the movable member 1 and the seat 2. One end of the first elastic element 80 abuts against the movable member 1, and the other end of the first elastic element 80 abuts against the seat 2. In this way, when the movable member 1 is pressed, the movable member 1 compresses the first elastic element 80; when the movable member 1 is released, the first elastic element 80 is released and pushes the movable member 1 to reset, thereby increasing the stability and convenience during operation.

In this embodiment, the rod body 622 is sleeved with a second elastic element 81. One end of the second elastic element 81 abuts against the seat 2, and the other end of the second elastic element 81 abuts against the blocking portion 624. In this way, the second elastic element 81 can be compressed at the same time when the rod body 622 of the pushing portion 62 extends out of the seat 2 to form a pushed-out state; the second elastic element 81 is released at the same time when the rod body 622 of the pushing portion 62 moves to the seat 2 to form a retracted state, thereby increasing stability and convenience during operation.

The present invention has been described with some preferred embodiments thereof and it is understood that the preferred embodiments are only illustrative and not intended to limit the present invention in any way and many changes and modifications in the described embodiments can be carried out without departing from the scope and the spirit of the invention that is intended to be limited only by the appended claims.

What is claimed is:

1. A movable handle, comprising:
a movable member, including a main body; and
a seat, movably assembled to the main body of the movable member such that the movable member being capable of moving, wherein the movable member includes an operation portion and a pushing portion, the operation portion is movably mounted on the seat, the pushing portion is movably mounted on the operation portion, and the operation portion controls the pushing portion to extend out of the seat to form a pushed-out state, or the operation portion controls the pushing portion to move to the seat to form a retracted state;
wherein one end of the operation portion includes a pusher portion, and one end of the pushing portion includes an abutting portion, the pusher portion abuts against the abutting portion.

2. The movable handle according to claim 1, wherein the pusher portion is an inclined body or a rolling body, and the abutting portion is a rolling body or an inclined body.

3. The movable handle according to claim 1, wherein one end of the operation portion includes a pusher portion, and one end of the pushing portion includes an abutting portion, the pusher portion abuts against the abutting portion, the pushing portion includes a rod body, the rod body includes a blocking portion, and the blocking portion includes a sliding portion for correspondingly sliding to abut against the seat.

4. The movable handle according to claim 1, wherein the pushing portion includes a rod body, the abutting portion is mounted at one end of the rod body, the rod body is sleeved with an elastic element and includes one or two blocking portions, the blocking portions abut against one end of the elastic element or abuts against the two ends of the elastic element respectively.

5. The movable handle according to claim 1, further including a rod body, the rod body including a blocking portion, the blocking portion including a limiting portion, and the seat including a corresponding limiting portion connecting to the limiting portion.

6. The movable handle according to claim 1, wherein further including a rod body, the rod body including a blocking portion, the blocking portion includes an anti-rotation portion, and the pushing portion includes a corresponding anti-rotation portion for anti-rotating correspondingly.

7. The movable handle according to claim 1, further including a blocking portion, the blocking portion including a limiting portion, and the seat including a corresponding limiting portion connecting to the limiting portion, the blocking portion including an anti-rotation portion, and the pushing portion including a corresponding anti-rotation portion for anti-rotating correspondingly, preventing the rolling body of the pushing portion from rotating during movement.

8. The movable handle according to claim 1, further including two elastic elements, one end of one of elastic elements abutting against the main body, and the other end abutting against the seat; one end of the other elastic element abutting against the pushing portion, and the other end abutting against the seat.

9. A movable handle, comprising:
a movable member, including a main body; and
a seat, movably assembled to the main body of the movable member, such that the movable member being capable of moving, wherein the movable member includes an operation portion, a pushing portion and a driving portion, the operation portion is movably mounted on the seat, the pushing portion is movably mounted on the operation portion, the driving portion is connected to the main body and the operation portion, the driving portion drives the operation portion, such that the operation portion controls the pushing portion to extend out of the seat to form a pushed-out state, or the operation portion controls the pushing portion to move to the seat to form a retracted state.

10. The movable handle according to claim 9, wherein one end of the operation portion includes a pusher portion, the pushing portion includes a rod body, one end of the rod body includes a blocking portion, and the pusher portion abuts against the abutting portion.

11. The movable handle according to claim 10, wherein the pusher portion is an inclined body or a rolling body, and the abutting portion is a rolling body or an inclined body.

12. The movable handle according to claim 10, wherein the rod body is sleeved with a first elastic element and includes a blocking portion, one end of the first elastic element abuts against the seat, and the other end of the first elastic element abuts against the blocking portion.

13. The movable handle according to claim 9, wherein one end of the operation portion includes a pusher portion, and one end of the pushing portion includes an abutting portion, the pusher portion abuts against the abutting portion.

14. The movable handle according to claim 13, wherein the pusher portion is a rolling body or an inclined body, and the abutting portion is an inclined body or a rolling body.

15. The movable handle according to claim 9, wherein the driving portion includes a rotating shaft and a driving member, the rotating shaft is movably mounted on the seat and connected to the main body, and the driving member is mounted on the rotating shaft and connected to the operation portion.

16. The movable handle according to claim 15, further comprising a second elastic element, one end of the second elastic element being connected to the seat, and the other end of the second elastic element being connected to the rotating shaft.

17. A movable handle, comprising:
a movable member, including a main body; and
a seat, movably assembled to the main body of the movable member such that the movable member being capable of moving, wherein the movable member includes an operation portion and a pushing portion, the operation portion is movably mounted on the seat, the pushing portion is movably mounted on the operation portion, and the operation portion controls the pushing portion to extend out of the seat to form a pushed-out state, or the operation portion controls the pushing portion to move to the seat to form a retracted state.

18. The movable handle according to claim 17, wherein a first elastic element is mounted between the movable member and the seat, one end of the first elastic element abuts against the movable member, and the other end of the first elastic element abuts against the seat.

19. The movable handle according to claim 17, wherein the operation portion includes a tie rod, a connecting rod, and a shaft body, the tie rod is movably connected to the movable member, the shaft body is movably mounted on the seat and connected to the tie rod and the connecting rod, the connecting rod is movably connected to the pushing portion.

20. The movable handle according to claim 17, wherein the pushing portion includes a rod body, and one end of the rod body includes a blocking portion.

21. The movable handle according to claim 20, wherein the rod body is sleeved with a second elastic element, one end of the second elastic element abuts against the seat, and the other end of the second elastic element abuts against the blocking portion.
